(19) United States
(12) Patent Application Publication
(10) Pub. No.: US 2011/0136973 A1
(43) Pub. Date: Jun. 9, 2011

(54) POLYBENZOTHIOPHENE POLYMERS AND PROCESS FOR THEIR PREPARATION

(75) Inventors: Marcel Kastler, Mannheim (DE); Florian Doetz, Singapore (SG); Junsik Lee, Lincoln, NE (US); Reuben D. Rieke, Lincoln, NE (US)

(73) Assignees: BASF SE, Ludwigshafen (DE); RIEKE METALS ,INC., Lincoln, NE (US)

(21) Appl. No.: 13/056,987

(22) PCT Filed: Jul. 31, 2009
(86) PCT No.: PCT/EP2009/059952

§ 371 Date: Feb. 1, 2011

Related U.S. Application Data
(60) Provisional application No. 61/188,744, filed on Aug. 11, 2008.

(51) Int. Cl. C08L 81/02; C08G 75/06; H01L 51/40

(52) U.S. Cl. 524/609; 528/9; 438/99; 257/E51.041

(57) ABSTRACT

A polymer comprising the group of the formula (I) in particular derivatives of Poly[benzothiophen-2.6-diyl].

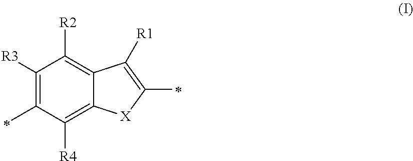

The present invention relates to polybenzothiophene polymers, to a process for their preparation and to their use as semiconductors or charge transport materials.

Field-effect transistors (FETs) composed of inorganic materials have been known for decades. A typical FET consists of various layers which are adjusted to the particular application.

As a result of the development of several conductive or semiconductive organic polymers, the development of organic thin-film transistors (OTFTs) based on organic materials as semiconductors has begun to an increased degree.

The use of organic semiconductors in OTFTs has some advantages over the inorganic semiconductors used to date. They can be processed in any form, from the fiber to the film, exhibit a high mechanical flexibility, can be produced at low cost and have a low weight. The significant advantage is, however, the possibility of producing the entire semiconductor component by deposition of the layers on a polymer substrate atmospheric pressure, for example by printing techniques, such that inexpensively producible FETs are obtained.

The performance of the electronic components depends essentially on the mobility of the charge carriers of the semiconductor material and the on/off ratio. An ideal semiconductor therefore has a minimum conductivity in the switched-off state and a maximum charge carrier mobility in the switched-on state (above 10⁻³ cm²V⁻¹s⁻¹). In addition, the semiconductor material has to be relatively stable to oxidation, i.e. has to have a sufficiently high ionization potential, since its oxidative degradation reduces the performance of the component.

EP 1510535 A1 describes polythieno(2,3-b)thiophenes which have a mobility of 3·10⁻³ or 1.7·10⁻² cm²V⁻¹s⁻¹ and on/off ratios of about 10⁶. WO2006/094645 A1 describes polymers which have one or more selenophene-2,5-diyl and one or more thiophene-2,5-diyl groups, while WO 2006/131185 discloses polythieno(3,4-d)thiazoles, and US 2005/0082525 A1 discloses benzo(1,2-b,4,5-b′)dithiophenes.

Polybenzothiophenes are generally known and have also been proposed as semiconductor materials for the production of electronic components. Owing to the structure, various structures are conceivable depending on the preparation method.

J. Electroanalytical Chem. 510 (2001), 29-34 describes polybenzothiophenes comprising the

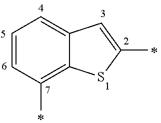

group. These 2,7-bonded polybenzothiophenes are prepared by electrooxidation in boron tetrafluoride diethyl etherate.

In addition to the 2,7-bonded polybenzothiophenes, in oxidative and cationic polymerization, owing to the charge distribution in the molecule, polymerization in the 2,5 position

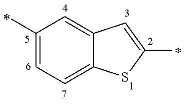

should also be expected.

In JP 2003330166 A, 2,3-bonded polybenzothiophene oligomers are used to prepare photopolymers.

A disadvantage of all polybenzothiophenes or analogs thereof obtained to date is their insufficient charge carrier mobilities. One of the reasons of the state of the art polythiophenes is deemed to be the reduced control of regularity during polymerization.

It is an object of the present invention to provide novel compounds for use as organic semiconductor materials, which are easy to synthesize, have high mobilities and a good oxidation stability, and can be processed readily.

It is a further object of the present invention to provide highly regioregular polythiophenes.

This object is achieved by polymers comprising the group

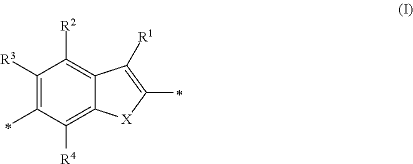

in which
R¹ to R⁴ are each independently selected from a) H, b) halogen, c)—CN, d)—NO₂, e) oxo, f)—OH, g)═C(R⁵)₂, h) a C₁₋₂₀ alkyl group, i) a C₂₋₂₀ alkenyl group, j) a C₂₋₂₀ alkynyl group, k) a C₁₋₂₀ alkoxy group, l) a C₁₋₂₀ alkylthio group, m) a C₁₋₂₀ haloalkyl group, n) a —Y—C₃₋₁₀ cycloalkyl group, o) a —Y—/C₆₋₁₄ aryl group, p) a —Y-3-12 membered cycloheteroalkyl group, or q) a —Y-5-14 membered heteroaryl group,
   wherein each of the C₁₋₂₀ alkyl group, the C₂₋₂₀ alkenyl group, the C₂₋₂₀ alkynyl group, the C₃₋₁₀ cycloalkyl group, the C₆₋₁₄ aryl group, the 3-12 membered cycloheteroalkyl group, and the 5-14 membered heteroaryl group is optionally substituted with 1-4 R⁵ groups, wherein R² and R³ may also together form a cyclic moiety,
R⁵ is independently selected from a) halogen, b) —CN, c) —NO₂, d) oxo, e) —OH, f) —NH₂, g) —NH(C₁₋₂₀ alkyl), h) —N(C₁₋₂₀ alkyl)₂, i) —N(C₁₋₂₀ alkyl)-C₆₋₁₄ aryl, j) —N(C₆₋₁₄ aryl)₂, k) —S(O)ₘH, l) —S(O)ₘ—C₁₋₂₀ alkyl, m) —S(O)₂OH, n) —S(O)ₘ—OC₁₋₂₀ alkyl, o) —S(O)ₘ—OC₆₋₁₄ aryl, p) —CHO, q) —C(O)—C₁₋₂₀ alkyl, r) —C(O)—C₆₋₁₄ aryl, s) —C(O)OH, t) —C(O)—OC₁₋₂₀ alkyl, u) —C(O)—OC₆₋₁₄ aryl, v) —C(O)NH₂, w) —C(O)NH—C₁₋₂₀ alkyl, x) —C(O)N(C₁₋₂₀ alkyl)₂, y) —C(O)NH—C₆₋₁₄ aryl, z) —C(O)N(C₁₋₂₀ alkyl)-C₆₋₁₄ aryl, aa) —C(O)N(C₆₋₁₄ aryl)₂, ab) —C(S)NH₂, ac) —C(S)NH—C₁₋₂₀ alkyl, ad) —C(S)N(C₁₋₂₀ alkyl)₂, ae) —C(S)N(C₆₋₁₄ aryl)₂, af) —C(S)N(C₁₋₂₀ alkyl)-C₆₋₁₄ aryl, ag) —C(S)NH—C₆₋₁₄ aryl, ah) —S(O)ₘNH₂, ai) —S(O)ₘNH(C₁₋₂₀ alkyl), aj) —S(O)ₘN(C₁₋₂₀ alkyl)₂, ak) —S(O)ₘNH(C₆₋₁₄ aryl), al) —S(O)ₘN(C₁₋₂₀ alkyl)-C₆₋₁₄ aryl, am) —S(O)ₘN(C₆₋₁₄ aryl)₂, an) —SiH₃, ao) —SiH(C₁₋₂₀ alkyl)₂, ap) —SiH₂(C₁₋₂₀ alkyl), aq) —Si(C₁₋₂₀ alkyl)₃, ar) a C₁₋₂₀ alkyl group, as) a C₂₋₂₀ alkenyl group, at) a C₂₋₂₀ alkynyl group, au) a C₁₋₂₀ alkoxy group, av) a C₁₋₂₀ alkylthio group, aw) a C₁₋₂₀ haloalkyl group, ax) a C₃₋₁₀ cycloalkyl group, ay) a C₆₋₁₄ aryl group, az) a haloaryl group, ba) a 3-12 membered cycloheteroalkyl group, or bb) a 5-14 membered heteroaryl group,
Y is independently selected from divalent C₁₋₆ alkyl group, a divalent C₁₋₆ haloalkyl group, or a covalent bond; and
m is independently selected from 0, 1, or 2,
X is O, S, Se, NR¹⁰, PR¹⁰, PR¹⁰R¹¹R¹², SiR¹⁰R¹¹ or CR¹⁰R¹¹,
R¹⁰, R¹¹, R¹² are each independently selected from H, a C₁₋₃₀ alkyl group, a C₂₋₃₀ alkenyl group, a C₁₋₃₀ haloalkyl group, -L-Ar¹, -L-Ar¹—Ar¹, -L-Ar¹—R¹³, or -L-Ar¹—Ar¹—R¹³;
R¹³ is independently selected from a C₁₋₂₀ alkyl group, a C₂₋₂₀ alkenyl group, a C₁₋₂₀ haloalkyl group, a C₁₋₂₀ alkoxy group, -L′-Ar², -L′-Ar²—Ar², -L′-Ar²—R¹⁵, or -L′-Ar²—Ar²—R¹⁵;
L is independently selected from —O—, —Y—O—Y—, —S—, —S(O)—, —Y—S—Y—, C(O)—, —NR¹⁴C(O)—, —NR¹⁴—, —SiR¹⁴₂—, —Y—[SiR¹⁴_{2]}—Y—, a divalent C₁₋₃₀ alkyl group, a divalent C₁₋₃₀ alkenyl group, a divalent C₁₋₃₀ haloalkyl group, or a covalent bond;
L′ is independently selected from —O—, —Y—O—Y—, —S—, —S(O)—, —Y—S—Y—, —C(O)—, —NR¹⁴C(O)—, —NR¹⁴—, —SiR¹⁴₂—, —Y—[SiR¹⁴_{2]}—Y—, a divalent C₁₋₂₀ alkyl group, a divalent C₁₋₂₀ alkenyl group, a divalent C₁₋₂₀ haloalkyl group, or a covalent bond;
Ar¹ is independently selected from a C₆₋₁₄ aryl group or a 5-14 membered heteroaryl group, each optionally substituted with 1-5 substituents independently selected from halogen, —CN, a C₁₋₆ alkyl group, a C₁₋₆ alkoxy group, and a C₁₋₆ haloalkyl group; and
Ar² is independently selected from a C₆₋₁₄ aryl group or a 5-14 membered heteroaryl group, each optionally substituted with 1-5 substituents independently selected from halogen, —CN, a C₁₋₆ alkyl group, a C₁₋₆ alkoxy group, and a C₁₋₆ haloalkyl group; and
R¹⁴ is independently selected from H, a C₁₋₆ alkyl group, or a —Y—C₆₋₁₄ aryl group,
R¹⁵ is independently selected from a C₁₋₂₀ alkyl group, a C₂₋₂₀ alkenyl group, a C₁₋₂₀ haloalkyl group, or a C₁₋₂₀ alkoxy group; and
   The advantage of the 2,6-bonded polybenzothiophenes, -furans, -selenophenes, etc., is that there is conjugation along the polymer chain, leading to considerably improved mobilities of the charge carriers. As used herein, “field effect mobility” or “mobility” refers to a measure of the velocity with which charge carriers induced by an external stimulus such as an electric field, for example, holes (or units of positive charge) in the case of a p-type semiconducting material and electrons in the case of an n-type semiconducting material, move through the material under the influence of an electric field.

A further advantage is that the 2-6-bonded polybenzothiophenes can be prepared with high regioregularity, further increasing the mobilities of the charge carriers. An extremely high regioregularity of 99% or more, preferably 99.5% or more, can be reached since the monomers can be prepared selectively so that only one monomer species is polymerized.

The terms 2-6-bonded polybenzothiophenes, -furans, -selenophenes, etc., refer to polymers comprising the structural unit benzothiophene-2,6-diyl or derivatives thereof and its analogs, respectively.

The present invention further provides for the use of the polymers according to the present invention as semiconductors or charge transport materials, especially in optical, electrooptical or electronic components, as thin-film transistors, especially in flat visual display units, or for radiofrequency identification tags (RFID tags) or in semiconductor components for organic light-emitting diodes (OLEDs), such as electroluminescent displays or backlighting for liquid-crystalline displays, for photovoltaic components or in sensors, as electrode material in batteries, as optical waveguides, for electrophotography applications such as electrophotographic recording.

The present invention further provides optical, electrooptical or electronic components comprising the polymer according to the present invention. Such components may, for example, FETs, integrated circuits (ICs), TFTs, OLEDs or alignment layers.

The invention is explained in detail hereinafter by way of example with reference to benzothiophene derivatives (X═S); it is pointed out explicitly that the remarks also apply to X═O (benzofuran derivatives), Se (benzoselenophene derivatives), NR¹⁰ (indole derivatives), PR¹⁰ (benzophosphene derivatives), PR¹⁰R¹¹R¹² or CR¹⁰R¹¹ (indene derivatives).

The polymers according to the present invention are suitable particularly as semiconductors, since they have the mobilities required for this purpose. The introduction of alkyl groups into the thiophene group improves its solubility and hence its processibility as solutions.

“Polymer” or “polymeric compound” generally refers to a molecule including at least two or more repeating units connected by covalent chemical bonds. The polymer or polymeric compound can have only one type of repeating unit as well as two or more types of different repeating units. In the former case, the polymer can be referred to as a homopolymer. In the latter case, the term “copolymer” or “copolymeric compound” can be used instead. The polymer or polymeric compound can be linear or branched. Branched polymers can include dendritic polymers, such as dendronized polymers, hyperbranched polymers, brush polymers (also called bottle-brushes), and the like. Unless specified otherwise, the assembly of the repeating units in the copolymer can be head-to-tail, head-to-head, or tail-to-tail. In addition, unless specified otherwise, the copolymer can be a random copolymer, an alternating copolymer, or a block copolymer.

The copolymerization of the benzothiophene structural units used as monomers with functionalized aromatic or unsaturated comonomers can have an advantageous influence on the solubility and the other properties of the products. The variation of the aromatic comonomers is one means of adjusting the band gap of the polymers in a controlled manner. This leads to an improved stability and higher carrier mobilities.

A “cyclic moiety” can include one or more (e.g., 1-6) carbocyclic or heterocyclic rings. In embodiments where the cyclic moiety is a polycyclic moiety, the polycyclic system can include one or more rings fused to each other (i.e., sharing a common bond) and/or connected to each other via a spiro atom. The cyclic moiety can be a cycloalkyl group, a heterocycloalkyl group, an aryl group, or a heteroaryl group, and can be optionally substituted as described herein.

“Halo” or “halogen” refers to fluoro, chloro, bromo, and iodo, preferably fluoro, chloro. or bromo.

“Alkyl” refers to a straight-chain or branched saturated hydrocarbon group. Examples of alkyl groups include methyl (Me), ethyl (Et), propyl (e.g., n-propyl and iso-propyl), butyl (e.g., n-butyl, iso-butyl, sec-butyl, tert-butyl), pentyl groups (e.g., n-pentyl, iso-pentyl, neopentyl), and the like. Alkyl groups preferably can have 1 to 30 carbon atoms, for example, 1-20 carbon atoms (i.e., C₁₋₂₀ alkyl group). Alkyl groups particularly preferably can have 1 to 6 carbon atoms, and can be referred to as a “lower alkyl group”. Alkyl groups can be substituted or unsubstituted. An alkyl group is generally not substituted with another alkyl group, an alkenyl group, or an alkynyl group.

“Haloalkyl” refers to an alkyl group having one or more halogen substituents. A haloalkyl group preferably can have 1 to 20 carbon atoms, in particular 1 to 10 carbon atoms. Examples of haloalkyl groups include CF₃, C₂F₅, CHF₂, CH₂F, CCl₃, CHCl₂, CH₂Cl, C₂Cl₅, and the like. Perhaloalkyl groups, i.e., alkyl groups where all of the hydrogen atoms are replaced with halogen atoms (e.g., CF₃ and C₂F₅), are included within the definition of “haloalkyl.” Haloalkyl groups that are not perhaloalkyl groups can be optionally substituted with 1-5 R⁵ and R⁵ is as defined under formula (I).

“Alkoxy” refers to —O-alkyl group. Examples of alkoxy groups include, but are not limited to, methoxy, ethoxy, propoxy (e.g., n-propoxy and isopropoxy), t-butoxy groups, and the like. The alkyl group in the —O-alkyl group can be optionally substituted with 1-5 R⁵ and R⁵ is as defined under formula (I).

“Alkylthio” refers to an —S-alkyl group. Examples of alkylthio groups include, but are not limited to, methylthio, ethylthio, propylthio (e.g., n-propylthio and isopropylthio), t-butylthio groups, and the like. The alkyl group in the —S-alkyl group can be optionally substituted with 1-5 R⁵ and R⁵ is as defined under formula (I).

“Arylalkyl” refers to an -alkyl-aryl group, where the arylalkyl group is covalently linked to the defined chemical structure via the alkyl group. An arylalkyl group is within the definition of an —Y—C₆₋₁₄ aryl group, where Y is as defined herein. An example of an arylalkyl group is a benzyl group (—CH₂—C₆H₅). An arylalkyl group can be optionally substituted, i.e., the aryl group and/or the alkyl group, can be substituted as disclosed herein.

“Alkenyl” refers to a straight-chain or branched alkyl group having one or more carbon-carbon double bonds. Preferred alkenyl groups are ethenyl, propenyl, butenyl, pentenyl, hexenyl, butadienyl, pentadienyl, hexadienyl groups. The one or more carbon-carbon double bonds can be internal (such as in 2-butene) or terminal (such as in 1-butene). In various embodiments, an alkenyl group can have 2 to 30 carbon atoms, for example, 2 to 20 carbon atoms (i.e., C₂₋₂₀ alkenyl group). In some embodiments, alkenyl groups can be substituted as disclosed herein. An alkenyl group is generally not substituted with another alkenyl group, an alkyl group, or an alkynyl group.

“Alkynyl” refers to a straight-chain or branched alkyl group having one or more triple carbon-carbon bonds. Preferred alkynyl groups include ethynyl, propynyl, butynyl, pentynyl. The one or more triple carbon-carbon bonds can be internal (such as in 2-butyne) or terminal (such as in 1-butyne). In various embodiments, an alkynyl group can have 2 to 30 carbon atoms, for example, 2 to 20 carbon atoms (i.e., C₂₋₂₀ alkynyl group). In some embodiments, alkynyl groups can be substituted as disclosed herein. An alkynyl group is generally not substituted with another alkynyl group, an alkyl group, or an alkenyl group.

“Cycloalkyl” refers to a non-aromatic carbocyclic group including cyclized alkyl, alkenyl, and alkynyl groups. A preferred cycloalkyl group can have 3 to 20 carbon atoms, for example, 3 to 14 carbon atoms (i.e., C₃₋₁₄ cycloalkyl group). A cycloalkyl group can be monocyclic (e.g., cyclohexyl) or polycyclic (e.g., containing fused, bridged, and/or spiro ring systems), where the carbon atoms are located inside or outside of the ring system. Any suitable ring position of the cycloalkyl group can be covalently linked to the defined chemical structure. Examples of cycloalkyl groups include cyclopropyl, cyclobutyl, cyclopentyl, cyclohexyl, cycloheptyl, cyclopentenyl, cyclohexenyl, cyclohexadienyl, cycloheptatrienyl, norbornyl, norpinyl, norcaryl, adamantyl, and spiro[4.5]decanyl groups, as well as their homologs, isomers, and the like. Cycloalkyl groups can be substituted as disclosed herein.

“Heteroatom” refers to an atom of any element other than carbon or hydrogen and includes, for example, nitrogen, oxygen, silicon, sulfur, phosphorus, and selenium.

“Cycloheteroalkyl” refers to a non-aromatic cycloalkyl group that contains at least one ring heteroatom selected from O, S, Se, N, P, and Si (e.g., O, S, and N), and optionally contains one or more double or triple bonds. A cycloheteroalkyl group can have 3 to 20 ring atoms, for example, 3 to 14 ring atoms (i.e., 3-14 membered cycloheteroalkyl group). One or more N, P, S, or Se atoms (e.g., N or S) in a cycloheteroalkyl ring may be oxidized (e.g., morpholine N-oxide, thiomorpholine S-oxide, thiomorpholine S,S-dioxide). Nitrogen or phosphorus atoms of cycloheteroalkyl groups can bear a substituent, in particular an alkyl group. Cycloheteroalkyl groups can also contain one or more oxo groups, such as oxopiperidyl, oxooxazolidyl, dioxo-(1H,3H)-pyrimidyl, oxo-2(1H)-pyridyl, and the like. Preferred cycloheteroalkyl groups include, among others, morpholinyl, thiomorpholinyl, pyranyl, imidazolidinyl, imidazolinyl, oxazolidinyl, pyrazolidinyl, pyrazolinyl, pyrrolidinyl, pyrrolinyl, tetrahydrofuranyl, tetrahydrothiophenyl, piperidinyl, piperazinyl. Cycloheteroalkyl groups can be substituted or unsubstituted.

“Aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. Preferably an aryl group can have from 6 to 16 carbon atoms in its ring system (e.g., C₆₋₁₆ aryl group), which can include multiple fused rings. Particularly preferably a polycyclic aryl group can have from 8 to 16 carbon atoms. Preferred aryl groups having only aromatic carbocyclic ring(s) include phenyl, 1-naphthyl (bicyclic), 2-naphthyl (bicyclic), anthracenyl (tricyclic), phenanthrenyl (tricyclic). Preferred polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Further preferred aryl groups include benzodioxanyl, benzodioxolyl, chromanyl, indolinyl groups, and the like. In some embodiments, aryl groups can be substituted as disclosed herein. In some embodiments, an aryl group can have one or more halogen substituents, and can be referred to as a “haloaryl” group. Perhaloaryl groups, i.e., aryl groups where all of the hydrogen atoms are replaced with halogen atoms (e.g., —C₆F₅), are included within the definition of “haloaryl.” In certain embodiments, an aryl group is substituted with another aryl group and can be referred to as a biaryl group. Each of the aryl groups in the biaryl group can be substituted or unsubstituted.

“Heteroaryl” refers to an aromatic monocyclic or polycyclic ring system containing at least one ring heteroatom. The heteroatom is preferably selected from oxygen (O), nitrogen (N), sulfur (S), silicon (Si), and selenium (Se) or a polycyclic ring system without being restricted thereto. Polycyclic heteroaryl groups include two or more heteroaryl rings fused together and monocyclic heteroaryl rings fused to one or more aromatic carbocyclic rings, non-aromatic carbocyclic rings, and/or non-aromatic cycloheteroalkyl rings. Preferably a heteroaryl group can have from 5 to 16 ring atoms and contain 1-5 ring heteroatoms (i.e., 5-16 membered heteroaryl group). Particular examples of heteroaryl groups include, for example, the 5- or 6-membered monocyclic and 5-6 bicyclic ring systems shown below:

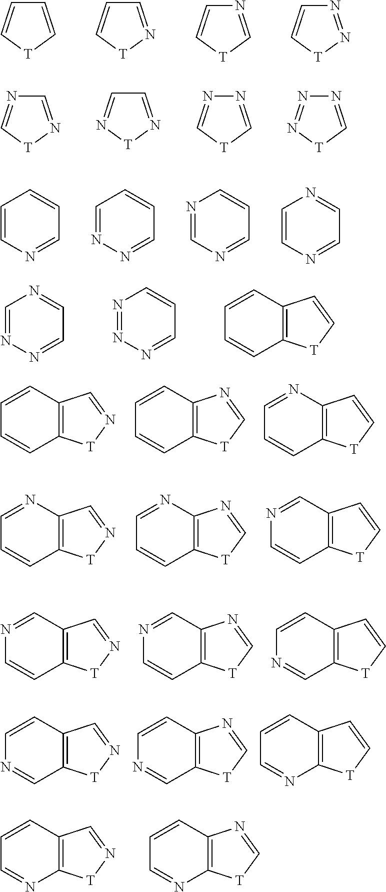

where T is O, S, NH, N-alkyl, N-aryl, N-(arylalkyl) (e.g., N-benzyl), SiH₂, SiH-(alkyl), Si(alkyl)₂, SiH-(arylalkyl), Si-(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be substituted as disclosed herein.

Compounds of the present teachings can include a “divalent group” defined herein as a linking group capable of forming a covalent bond with two other moieties. For example, compounds of the present teachings can include a divalent C₁₋₂₀ alkyl group, such as, for example, a methylene group.

Preferred polymers are those of the formula (IIa)

-[(A)ₐ-(B)_{b}-(C)_{c}-(D)_{d}]ₙ- (IIa)

in which
n is greater than or equal to 2,
A and C are independently, and in the case of multiple presence each independently, a group of the formula (I),
B and D are independently, and in the case of multiple presence each independently, a group selected from CR¹⁰═CR¹¹, —C≡C—, arylene and heteroarylene, which may optionally be substituted by one or more R¹ groups,
a, b, c, d are each independently 0 or an integer value from 1 to 10, with the condition that a+b+c+d are >0 and, in at least one of the repeating [(A)ₐ-(B)_{b}-(C)_{c}-(D)_{d}] groups, at least one a and one c is greater than or equal to 1 and at least one a and d is greater than or equal to 1, and
n, R¹⁰ and R¹¹ are each as defined in formula (I), and where the repeating [(A)ₐ-(B)_{b}-(C)_{c}-(D)_{d}] groups may be the same or different.

The polymers may be end-capped by several groups as known from the prior art. Preferred end groups are H, substituted or unsubstituted phenyl or substituted or unsubstituted thiophene, without being restricted thereto.

In the polymers, the repeating structural units [(A)ₐ-(B)_{b}-(C)_{c}-(D)_{d}], in the case of repeated occurrence, may be selected independently of one another, such that a polymer may have identical or different repeating structural units [(A)ₐ-(B)_{b}-(C)_{c}-(D)_{d}].

The polymers, in contrast to the 2,3-, 2,5- or 2,7-bonded polythiophenes of the prior art, which are obtained by oxidation, are 2,6-bonded polybenzothiophenes or derivatives thereof. The following numbering is used hereinafter:

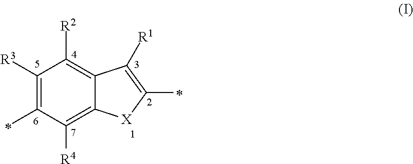

Polymers in the context of the present invention are all nonmonomeric compounds in which the structural unit according to the present invention repeats at least once. Polymers in the context of the present invention therefore also include dimers, trimers, and oligomers.

The polymers may be homopolymers of the group of the formula (I), and also copolymers of the group of the formula (I) with other monomer units. Copolymers may be random, alternating or block polymers. Examples of random copolymers are those with the sequence -A-B—C—C—B-D-A-D-B-D- or -A-C—C-A-C-A-C-A-A-C—. Examples of alternating copolymers are those with the sequence -A-B—C-D-A-B—C-D-A-B— or -A-C-A-C-A-C-A-C-A-C—. Examples of block copolymers are those with the sequence -A-A-A-B—B—B—C—C-D-D- or -A-A-A-A-B—B—B—B-A-A-.

It is preferred when A, B, C and D together form a conjugated system.

Preference is given to polymers which have one or more repeating structural units [(A)ₐ-(B)_{b}-(C)_{c}-(D)_{d}] in which a is 1, c is 0 and b or d is an integer value from 1 to 10, preferably 1, 2, 3, 4, 5 or 6. Particular preference is given to polymers which consist of these repeating structural units.

Preference is also given to polymers, especially of the formulae (IIa) and (IIb), which have identical repeating structural units. Preference is likewise given to polymers of the formulae (IIa) and (IIb) in which R¹, R², R³ and R⁴ are each H, halogen or C₁ to C₂₀ alkyl.

Preference is also given to polymers, especially those of the formulae (IIa) and (IIb), whose degree of polymerization (number n of repeating structural units) is from 2 to 5000, more preferably from 10 to 5000, particularly preferably from 100 to 1000.

Preference is also given to polymers whose molar mass is from 5000 to 200 000, more preferably from 20 000 to 100 000.

Preference is also given to polymers of the formulae (IIa) and (IIb) in which at least one of B and D is arylene or heteroarylene, which are unsubstituted or substituted by one or more L groups. L may be F, Cl, Br, or alkyl, alkoxy, alkylcarbonyl or alkoxycarbonyl groups having from 1 to 20 carbon atoms, where one or more hydrogen atoms optionally by F or Cl, or C₁-C₂₀-alkyl which is unsubstituted or substituted by one or more fluorine atoms, C₁-C₂₀-alkoxy, C₁₋₂₀-alkenyl, C₁-C₂₀-alkynyl, C₁-C₂₀-thioalkyl, C₁-C₂₀-silyl, C₁₋₂₀-ester, C₁₋₂₀-amino, C₁-C₂₀-fluoroalkyl, more preferably C₁-C₂₀-alkyl or C₁-C₂₀-fluoroalkyl.

Preference is also given to polymers of the formulae (IIa) and (IIb) in which:
one of b and d is 0 or a and b are each 0,
b and d are each independently 0, 1, 2, 3 or 4,
a and c are each independently 0, 1 or 2,
B and/or D is C—C or arylene or heteroarylene,
B and/or D is R²⁰C═CR²¹, where at least one of the R²⁰ and R²¹ radicals is preferably different than H,
B and/or D is thiophene-2,5-diyl which is unsubstituted or mono- or polysubstituted by L as defined above,
B and/or D is thieno[3,2-b] which is unsubstituted or mono- or polysubstituted by L as defined above,
B and/or D is selected from the formulae (IIIa) to (IIIe),
n is greater than 5, more preferably an integer from 5 to 5000,
R¹ to R⁴ are each selected from H and C₁-C₂₀-alkyl which is unsubstituted or substituted by one or more fluorine atoms, C₁-C₂₀-alkoxy, C₁-C₂₀-alkenyl, C₁-C₂₀-alkynyl, C₁-C₂₀-thioalkyl, C₁-C₂₀-silyl, C₁-C₂₀-ester, C₁-C₂₀-amino, C₁-C₂₀-fluoroalkyl, and optionally substituted aryl or heteroaryl, more preferably C₁-C₂₀-alkyl or C₁-C₂₀-fluoroalkyl,
R⁷ and R⁸ are each selected from H, halogen, Sn(R²⁰)₃, CH₂Cl, COH, CH═CH₂, SiR²⁰R²¹R²², which are unsubstituted or substituted by aryl or heteroaryl,
C is A′ where A′ is a mirror image of A reflected at right angles to the polymer chain, i.e. the bonding, instead of being via carbon atoms 2 and 6, in a mirror image, is via carbon atoms 6 and 2.

Copolymers in which one or more of B and D are acetylene or arylene or heteroarylene have an improved solubility and, by virtue of the higher molar mass, improved processibility.

In the case of use of arylene or heteroarylene for B or D, preference is given to using mono-, bi- or tricyclic, aromatic or heteroaromatic groups having up to 25 carbon atoms, where the rings may be fused and in which the heteroaromatic group comprises at least one heteroatom in the ring, which is preferably selected from N, O and S. It may be unsubstituted or substituted by one or more of F, Cl, Br, I, CN, and straight-chain, branched or cyclic alkyl having from 1 to 20 carbon atoms, which may be unsubstituted or mono- or polysubstituted by F, Cl, Br, I, —CN or —OH, and in which one or more nonadjacent —CH₂— groups may independently be replaced by —O—, —S—, —NH—, —NR¹⁰—, —SiR¹⁰R¹¹—, —CO—, —COO—, OCO—, —OCO—O, —S—CO—, —CO—S—, —CH═CH— or —C≡C—, such that oxygen and sulfur atoms are not bonded directly to one another, where R¹⁰ and R¹¹ are as defined herein.

B and/or D preferably have a planar and highly conjugated cyclic core.

Preferably B and/or D have a reduction potential greater than (i.e., more positive than) −2.6 V, more preferably greater than or equal to about −2.2 V, most preferably greater than or equal to about −1.2 V.

Preferably B and/or D are independently selected from a monocyclic or polycyclic moiety (e.g., a fused-ring moiety) having one or more five-, six-, and/or seven-membered rings and optionally substituted with R¹ to R⁴ groups as defined in formula (I). In particular embodiments, B and/or D can include at least one electron-withdrawing group.

B and/or D can include one or more electron-withdrawing groups, independently selected from a carbonyl group, a cyano group, and a dicyanovinylidene group. A and/or B can be a monocyclic moiety or a polycyclic moiety including a monocyclic ring (e.g., a 1,3-dioxolane group or a derivative thereof including optional substituents and/or ring heteroatoms) covalently bonded to a second monocyclic ring or a polycyclic system via a spiroatom (e.g., a spiro carbon atom).

Preferred groups B or D or B and D are independently selected from:

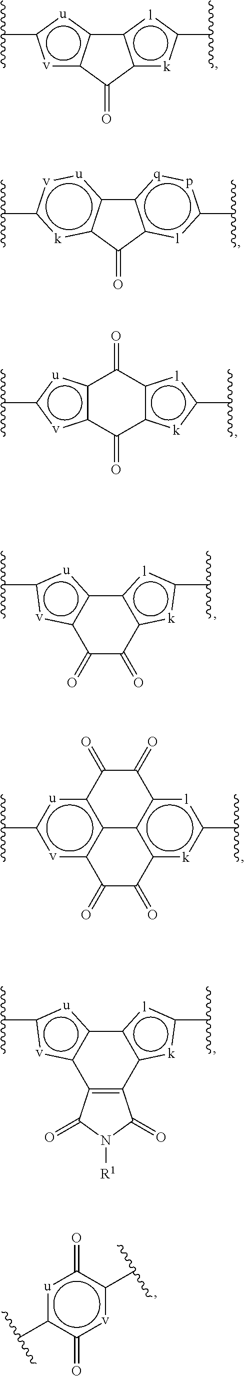

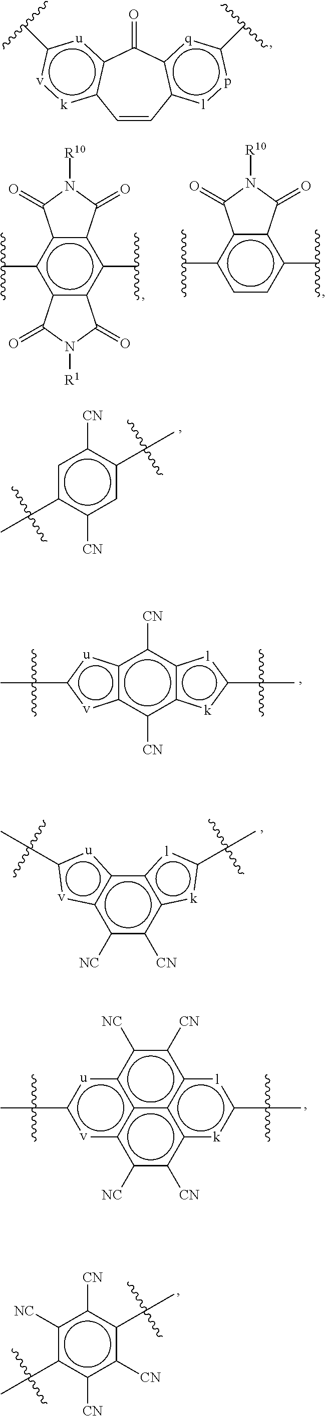

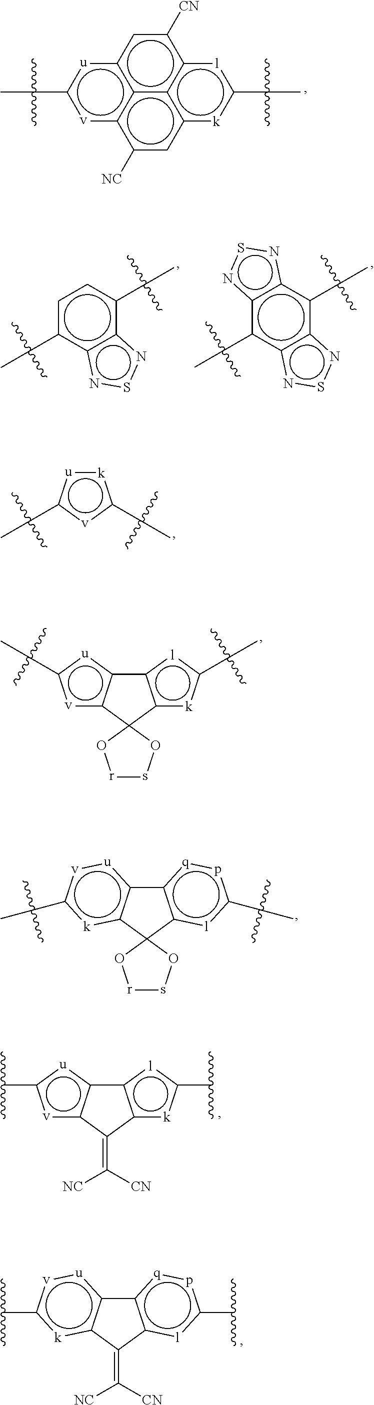

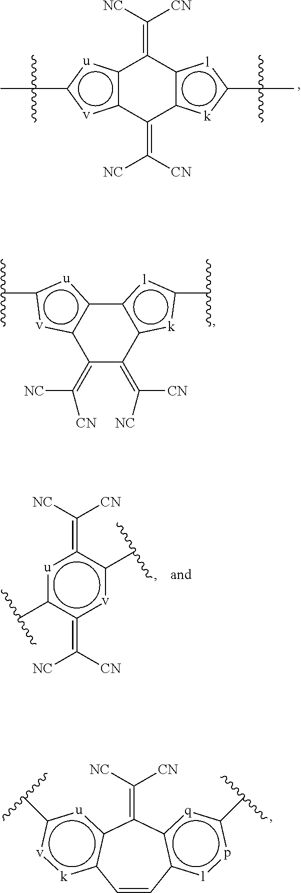

where k, l, p, q, u, and v independently are —S—, —C═C—, ═CH—, ═CR¹—, ═SiH—, ═SIR¹—, ═N—, or ═P—; and r and s independently are CH₂, CHR¹, or C(R¹)₂, where R¹ and R¹⁰ are as defined under formula (I). For example, each of k, l, p, q, u, and v independently can be —S—, —C═C—, or ═CH—. Each of r and s can be CH₂.

In certain embodiments, repeating units B and/or D can have a cyclic core that includes one or more thienyl or phenyl groups, where each of these groups can be optionally substituted with R¹ to R⁴ groups as defined in formula (I). Preferred repeating units B and/or D are selected from:

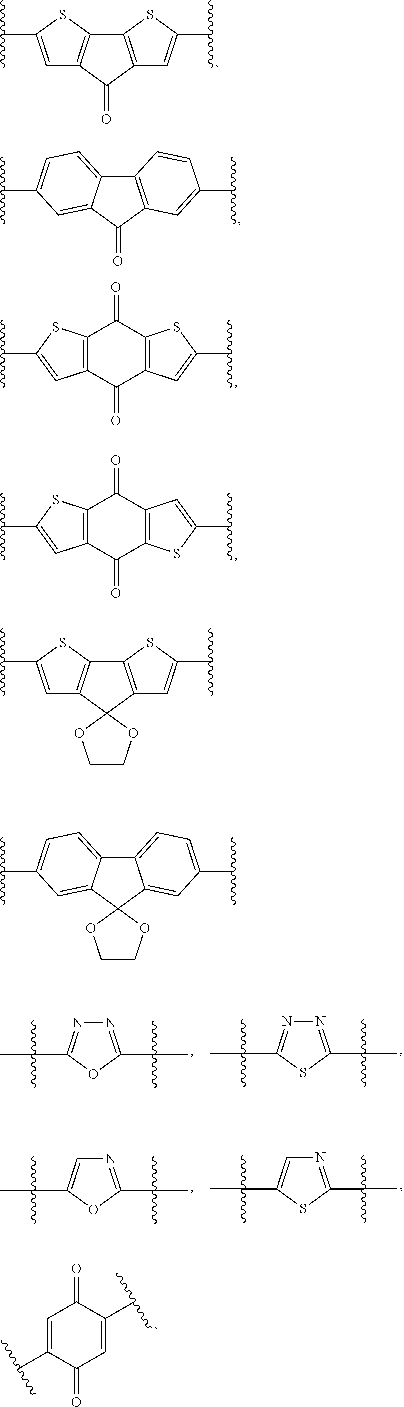

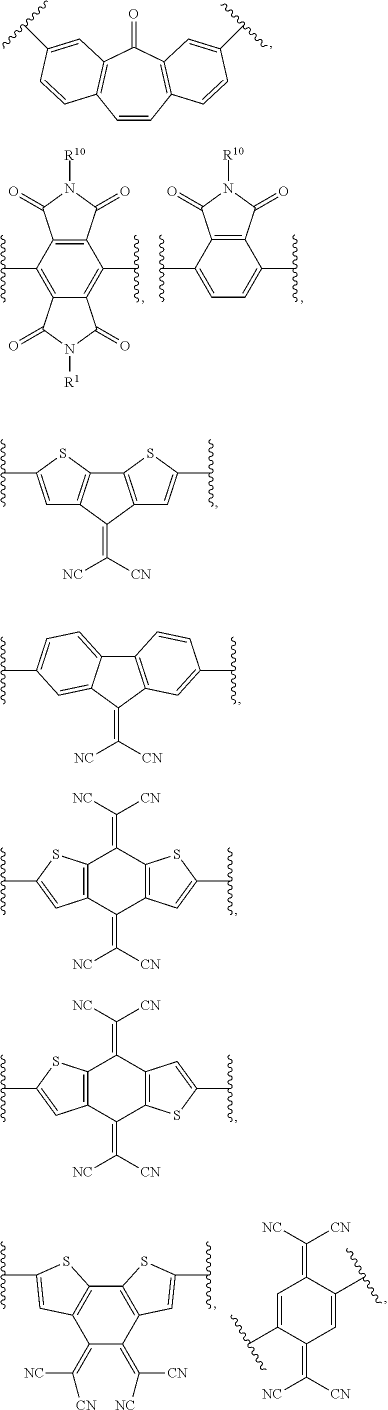

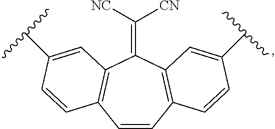

wherein R¹⁰ has the meanings as given in formula (I).

For the avoidance of doubt the star and the wiggly line in the structures are used interchangeably.

Preferably, at least one of R¹ to R⁴ independently can be an electron-withdrawing group. For example, at least one of R¹ to R⁴ independently can be a halogen, —CN, —NO₂, oxo, —OH, ═C(R⁵)₂, a C₁₋₂₀ alkoxy group, a C₁₋₂₀ alkylthio group, or a C₁₋₂₀ haloalkyl group. More preferably R¹ to R⁴ can be a halogen (e.g., F, Cl, Br, or I), —CN, a C₁₋₆ alkoxy group, —OCF₃, or —CF₃. Most preferably at least one of R¹ to R⁴ independently can be —CN, F, Cl, Br, or I.

The electron-donating or electron-withdrawing properties of several hundred of the most common substituents, reflecting all common classes of substituents have been determined, quantified, and published. The most common quantification of electron-donating and electron-withdrawing properties is in terms of Hammett σ values. Hydrogen has a Hammett σ value of zero, while other substituents have Hammett σ values that increase positively or negatively in direct relation to their electron-withdrawing or electron-donating characteristics. Substituents with negative Hammett σ values are considered electron-donating, while those with positive Hammett σ values are considered electron-withdrawing. See Lange's Handbook of Chemistry, 12th ed., McGraw Hill, 1979, Table 3-12, pp. 3-134 to 3-138, which lists Hammett σ values for a large number of commonly encountered substituents and is incorporated by reference herein. It should be understood that the term “electron-accepting group” can be used synonymously herein with “electron acceptor” and “electron-withdrawing group”. In particular, an “electron-withdrawing group” (“EWG”) or an “electron-accepting group” or an “electron-acceptor” refers to a functional group that draws electrons to itself more than a hydrogen atom would if it occupied the same position in a molecule. Examples of electron-withdrawing groups include, but are not limited to, halogen or halide (e.g., F, Cl, Br, I), —NO₂, —CN, —NC, —OH, —OR⁰, —SH, —SR⁰, —S(R⁰)₂⁺, —NH₂, —NHR⁰, —NR⁰₂, —N(R⁰)₃⁺, —SO₃H, —SO₂R⁰, —SO₃R⁰, —SO₂NHR⁰, —SO₂N(R⁰)₂, —COOH, —COR⁰, —COOR⁰, —CONHR⁰, —CON(R⁰)₂, C₁₋₁₀ haloalkyl groups, C₆₋₁₄ aryl groups, and 5-14 membered heteroaryl groups; where R⁰ is a C₁₋₁₀ alkyl group, a C₂₋₁₀ alkenyl group, a C₂₋₁₀ alkynyl group, a C₁₋₁₀ haloalkyl group, a C₁₋₁₀ alkoxy group, a C₆₋₁₄ aryl group, a C₃₋₁₄ cycloalkyl group, a 3-14 membered cycloheteroalkyl group, and a 5-14 membered heteroaryl group, each of which can be optionally substituted with 1-5 R⁵ and R⁵ is as defined in formula (I).

Preferred groups B and/or D may also be selected from:

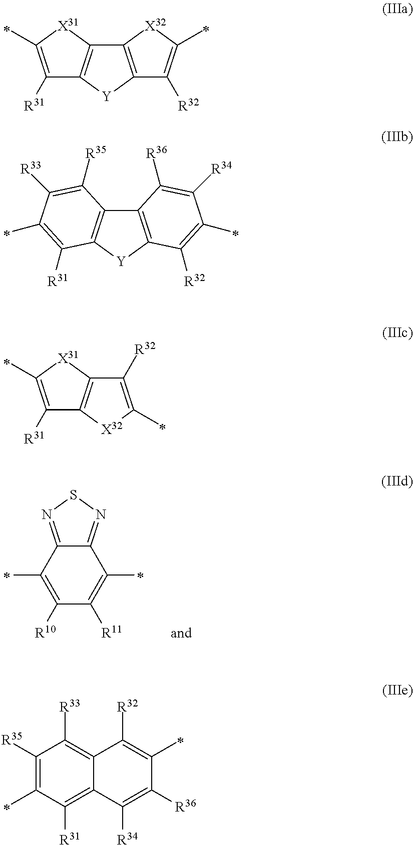

wherein
X³¹ and X³² are each independently selected from S, Se, NR¹⁰, PR¹⁰, PR¹⁰R¹¹R¹² or CR¹⁰R¹¹
Y is selected from CR¹⁰R¹¹, C═O, C═S, C═N—R¹⁰, C═C(CN)₂,
R³¹ to R³⁶ each independently have the meanings of one of R¹ to R⁴ as defined under formula (I)
R¹⁰, R¹¹ each independently have the meanings as defined under formula (I).

Preferred substituents X³¹ and X³² may each independently be selected from S and Se.

Preferred substituents Y may be selected from CR¹⁰R¹¹, C═O and C═C(CN)₂. Preferred substituents R³¹ to R³⁶ are selected from C₁ to C₁₂ alkyl, C₆ to C₂₀ alkylaryl, arylalkyl and aryl. Preferred substituents R¹⁰, R¹¹ may be selected from C₁ to C₁₂ alkyl, C₆ to C₂₀ alkylaryl, C₆ to C₂₀ arylalkyl and C₅ to C₂₀ aryl and heteroaryl, which may be unsubstituted or substituted, or R¹⁰ and R¹¹ together form an aromatic or heteroaromatic cyclic moiety.

In the case of use of aryl or heteroaryl as R¹ to R⁴, preference is given to using mono-, bi- or tricyclic aromatic or heteroaromatic groups with up to 25 carbon atoms, where the rings may be fused and in which the heteroaromatic group comprises at least one heteroatom in the ring, which is preferably selected from N, O and S. It may be unsubstituted or substituted by one or more of halogen or —CN, and straight-chain, branched or cyclic alkyl having from 1 to 20 carbon atoms, which may be unsubstituted or mono- or polysubstituted by halogen, —CN or —OH, and in which one or more nonadjacent —CH₂— groups may each independently be replaced by —O—, —S—, —NH—, —NR¹⁰—, —SiR¹⁰R¹¹—, —CO—, —OCO—, OCO—, —OCO—O, —S—CO—, —CO—S—, —CH═CH— or —C≡C—, such that oxygen and/or sulfur atoms are not bonded directly to one another.

Particularly preferred aryl and heteroaryl groups are phenyl, fluorinated phenyl, pyridine, pyrimidine, biphenyl, naphthalene, optionally fluorinated or alkylated, or fluoroalkylated benzo[1,2-b:4,5-b′]dithiophene, optionally fluorinated or alkylated, or fluoroalkylated thieno[3,2-b]thiophene, optionally fluorinated or alkylated, or fluoroalkylated 2,2-dithiophene, thiazole and oxazole, all of which may be unsubstituted or mono- or polysubstituted by L as defined above.

Preferably, at least one of R¹ to R⁴ is selected from alkyl or alkoxy, which may be straight-chain or branched, preference being given to straight-chain. In addition, at least one of the R¹ to R⁴ radicals preferably has from 2 to 8 carbon atoms.

More preferably, at least one of the R¹ to R⁴ radicals is selected from propyl, butyl, pentyl, hexyl, heptyl, octyl, ethoxy, propoxy, butoxy, pentoxy, hexyloxy, heptoxy or octoxy.

Fluorinated alkyl or alkoxy is preferably straight-chain (O)CᵢF₂ᵢ₊₁, where i is an integer from 1 to 20, especially from 1 to 15, more preferably (O)CF₃, (O)C₂F₅, (O)C₃F₇, (O)C₄F₉, (O)C₅F₁₁, (O)C₆F₁₃, (O)C₇F₁₅ or (O)C₈F₁₇.

CR¹⁰═CR¹¹ is preferably —CH═CH—, —CH═CF—, —CF═CH—, —CF═CF—, —CH═C(CN)— or —C(CN)═CH—.

Halogen is preferably F, Br or Cl.

Heteroatoms are preferably selected from N, O and S.

Examples of preferred homopolymers of benzothiophene or its derivatives are those of the formula (IVa) where C is A′ and B and D are each 0:

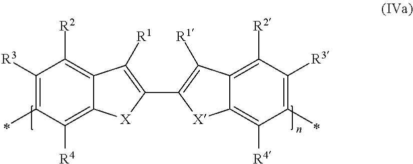

or those of the formula (IVb) where B, C and D are each 0:

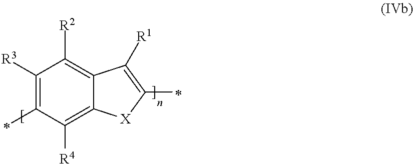

where n, X and R¹ to R⁴ are each as defined for formula (I), X′ independently may have the meanings of X, and R^{1′} to R^{4′} are each independently, and independently of R¹ to R⁴, as defined for R¹ to R⁴.

Examples of preferred copolymers of benzothiophene or its derivatives are those of formula Va

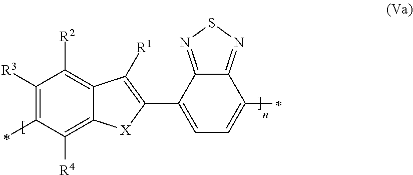

The polymers according to the present invention can be prepared by methods which are already known. Preferred synthesis routes are described hereinafter.

The polymers comprising 2,6-bonded polybenzothiophene groups of the formula (I) or analogs thereof can preferably be prepared using the following reaction scheme:

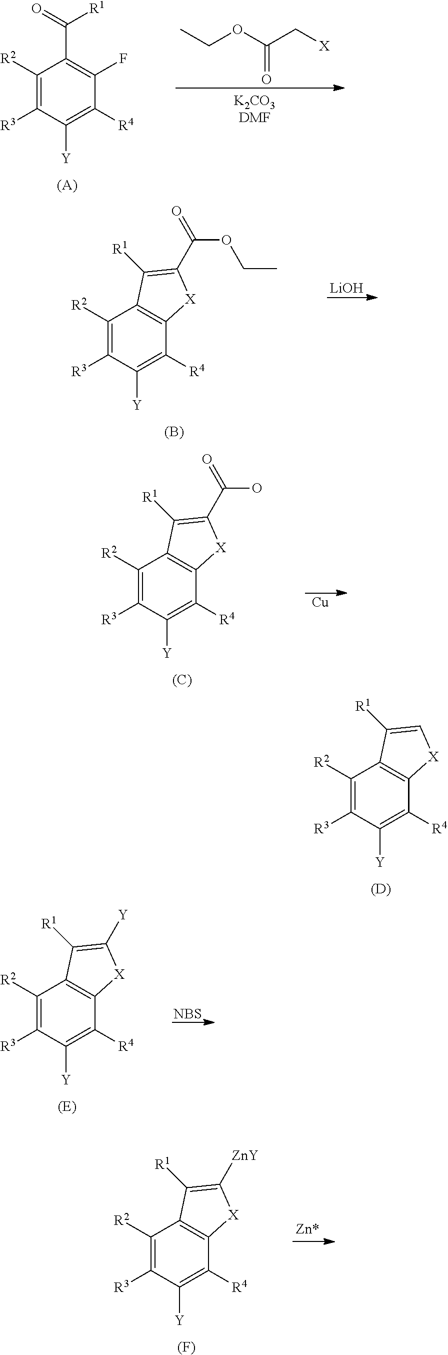

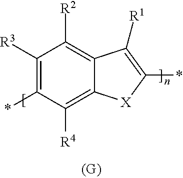

In this scheme, X, R¹ to R⁴ are each as defined for formula (I) and Y is Cl, Br, I or CN.

Compound (B) may be prepared from (A) according to the methods described in J. Med. Chem. 2007, 50, 4799, scheme 5. If R1 is not H the respective ketone has to be used instead of the aldehyde.

Compounds (C) and (D) may be prepared from (B) according to the methods described in J. Org. Chem., 72 (2007), 443, scheme 2, steps 11 to 12 and 12 to 13.

Compound E may be prepared from compound D by bromination in NBS.

Compound F may be formed by reacting compound E with active zinc at room temperature. Zinc may be replaced by manganese or magnesium.

Examples of copolymers of the formula (IIa) where C is A′, B is phenyl and D is 0 are preferably obtainable according to:

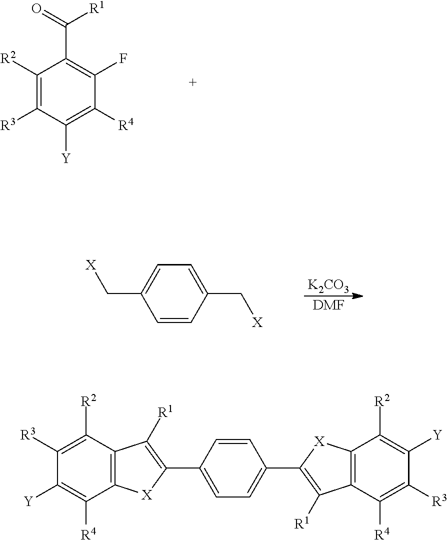

In this scheme, X, R¹ to R⁴ are each as defined for formula (I) and Y is Cl, Br, I or CN. Preferably X may be S and Y may be Br.

Examples of copolymers of the formula (IIa) where C and D are each 0 and B is phenyl are preferably obtainable according to:

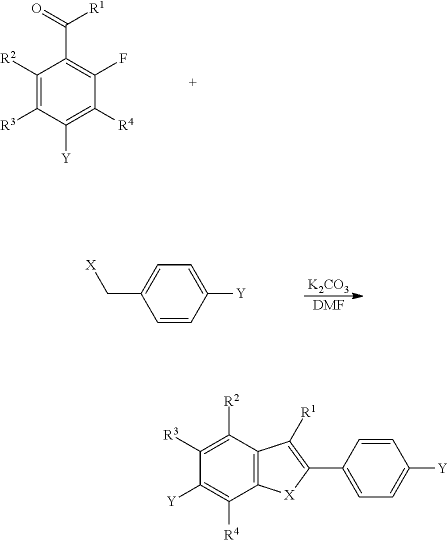

In this scheme, X, R¹ to R⁴ are each as defined for formula (I) and Y is Cl, Br, I or CN. Preferably X may be S and Y may be Br.

Other polymers with phenyl derivatives or other aromatics can be prepared analogously to the schemes given.

The invention comprises both the oxidized and the reduced forms of the polymers according to the present invention. Either a deficiency or an excess of electrons leads to the formation of a delocalized ion which has a high conductivity. This can be done by doping with customary dopants. Dopants and doping processes are common knowledge and are known, for example, from EP-A-0 528 662, U.S. Pat. No. 5,198,153 or WO 96/21659. Suitable doping processes comprise, for example, doping with a doping gas, electrochemical doping in a solution comprising the dopant, by thermal diffusion and by ion implantation of the dopant into the semiconductor material.

In the case of use of electrons as charge carriers, preference is given to using halogens (e.g. I₂, Cl₂, Br₂, ICl, ICl₃, IBr and IF), Lewis acids (e.g. PF₅, AsF₅, SbF₅, BF₃, BCl₃, SbCl₅, BBr₃ and SO₃), inorganic acids (e.g. HF, HCl, HNO₃, H₂SO₄, HClO₄, FSO₃H and ClSO₃H), organic acids or amino acids, transition metal compounds (e.g. FeCl₃, FeOCl, Fe(ClO₄)₃, Fe(4-CH₃C₆H₄SO₃)₃, TiCl₄, ZrCl₄, HfCl₄, NbF₅, NbCl₅, TaCl₅, MoF₅, MoCl₅, WF₅, WCl₆, UF₆ and LnCl₃(where Ln is a lanthanoid)), anions (e.g. Cl⁻, Br⁻, I⁻, I₃⁻, HSO₄⁻, SO₄²⁻, NO₃⁻, ClO₄⁻, BF₄⁻, PF₆⁻, AsF₆⁻, SbF₆⁻, FeCl₄⁻, Fe(CN)₆³⁻, and anions of different sulfonic acids such as aryl-SO₃⁻). In the case of use of holes as charge carriers, as dopants, for example, are cations (e.g. H⁺, Li⁺, Na⁺, K⁺, Rb⁺ and Cs⁺), alkali metals (e.g. Li, Na, K, Rb, and Cs), alkaline earth metals (e.g. Ca, Sr and Ba), O₂, XeOF₄, (NO₂⁺) (SbF₆⁻), (NO₂⁺) (SbCl₆⁻), (NO₂⁺) (BF₄⁻), AgClO₄, H₂IrCl₆, La(NO₃)₃, FSO₂OOSO₂F, Eu, acetylcholine, R₄N⁺, R₄P⁺, R₆As⁺ and R₃S⁺, where R is an alkyl group.

The conductive form of the polymers according to the present invention can be used as an organic conductor, for example charge injection layers and ITO planarizing layers in organic light-emitting diodes (OLEDs), flat screens and touch screens, antistatic films, printed circuits and capacitors, without being restricted thereto.

The polymers according to the present invention can be used to produce optical, electronic and semiconductor materials, especially as charge transport materials in field-effect transistors (FETs), for example as components of integrated circuits (ICs), ID tags or TFTs. Alternatively, they can be used in organic light-emitting diodes (OLEDs) in electroluminescent displays or as backlighting, for example liquid-crystal displays (LCDs), in photovoltaic applications or for sensors, for electrophotographic recording and other semiconductor applications.

Since the polymers according to the present invention have good solubility, they can be applied to the substrates as solutions. Layers can therefore be applied with inexpensive processes, for example spin-coating.

Suitable solvents or solvent mixtures comprise, for example, alkanes, aromatics, especially their fluorinated derivatives.

FETs and other components comprising semiconductor materials, for example diodes, can be used advantageously in ID tags or security labels in order to indicate authenticity and to prevent forgeries of valuable items such as banknotes, credit cards, identity documents such as ID cards or driving licenses or other documents with pecuniary advantage such as rubber stamps, postage stamps or tickets, etc.

Alternatively, the polymers according to the present invention can be used in organic light-emitting diodes (OLEDs), for example in displays or as backlighting for liquid-crystal displays (LCDs). Typically, OLEDs have a multilayer structure. A light-emitting layer is generally embedded between one or more electron- and/or hole-transporting layers. When an electrical voltage is applied, the electrons or holes can migrate in the direction of the emitting layer, where their recombination to the excitation and subsequent luminescence of the luminophoric compounds in the emitting layer. The polymers, materials and layers may, according to their electrical and optical properties, find use in one or more of the transport layers and/or emitting layers. When the compounds, materials or layers are electroluminescent or have electroluminescent groups or compounds, they are particularly suitable for the emitting layer.

Like the processing of suitable polymers for use in OLEDs, the selection is common knowledge and is described, for example, in Synthetic Materials, 111-112 (2000), 31-34 or J. Appl. Phys., 88 (2000) 7124-7128.

All documents cited herein are incorporated in the present patent application by reference. All quantitative data (percentages, ppm, etc.) are based on the weight, based on the total weight of the mixture, unless stated otherwise.

### EXAMPLES

### Example 1

### Preparation of (Poly (3-nonylbenzo[b]thiophene-2,6-diyl)

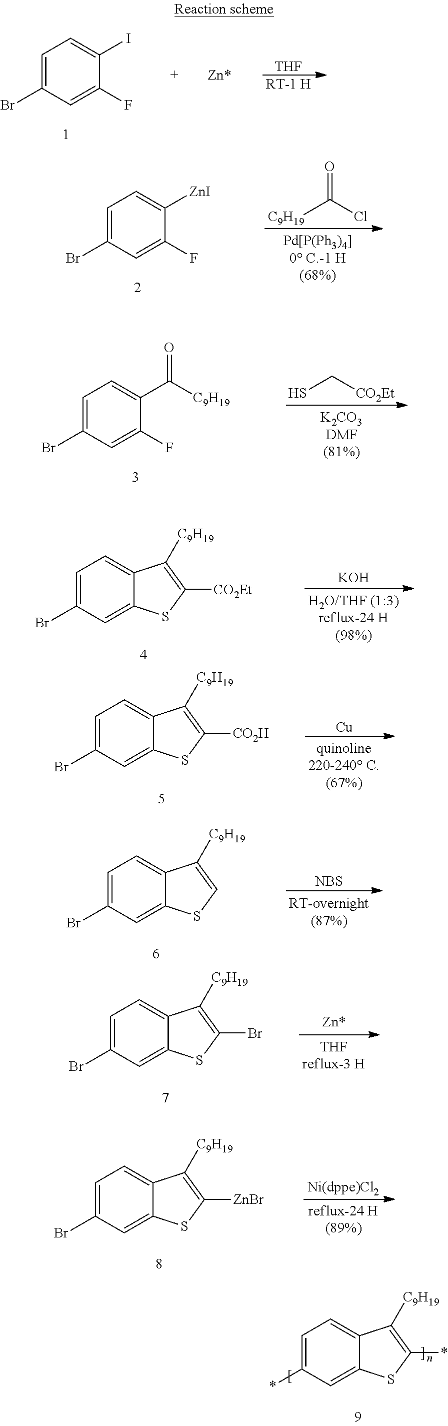

Active zinc was prepared as described in WO 93/15086.

4-Bromo-2-fluorophenylzinc iodide (2): To a slurry of active zinc (21.00 g, 321.2 mmole) in THF (210 ml) was added 4-bromo-2-fluoro-1-iodobenzene (75.23 g, 250.0 mmole) in THF (40 ml) at room temperature under Ar, and the mixture was stirred for 1 h. The exothermic reaction made the mixture reflux throughout the addition of the halide solution. THF (250 ml) was added into the reaction mixture and the mixture was stood for overnight to settle down the excess zinc. The top organozinc solution was transferred into a clean flask.

1-(4-Bromo-2-fluoro-phenyl)decan-1-one (3): To a mixture of Pd(PPh3)₄(1.35 g, 1.2 mmole) and 4-bromo-2-fluorophenylzinc iodide (2) (0.5 M solution in THF, 500 ml, 250.0 mmole) was added decanoyl chloride (47.68 g, 250.0 mmole) at 0° C. under Ar, and the reaction mixture was stirred for 1 h. The reaction was quenched with 3 M HCl (250 ml) and THF was removed by a rotary evaporator. The residue was extracted 2 times with ether (250 mL) and the organic layer was washed with 7.5% NH₄OH aqueous solution, saturated Na2S2O3 solution, saturated NaHCO3 solution, and brine, dried over MgSO4, and concentrated. A fractional distillation gave a product (55.63 g, 68%) as a colorless oil at 147° C./0.86 mmHg and the product was solidified later, mp 31-32° C.

Ethyl 6-bromo-3-nonylbenzo[b]thiophene-2-carboxylate (4): A mixture of 1-(4-bromo-2-fluoro-phenyl)decan-1-one (3) (52.68 g, 160.0 mmole), K2CO3 (28.75 g, 208.0 mmole) and DMF (320 ml) was cooled to 0° C. and ethyl mercaptoacetate (21 ml, 23.02 g, 191.6 mmole) was added into the reaction mixture via a syringe. The cold bath was removed and the reaction mixture was stirred for 2 h at room temperature and then heated for 3 h at 100° C. Water (500 ml) was added into the reaction mixture and the mixture was stirred until all solids were dissolved. The mixture was extracted 3 times with ether (300 ml) and the organic layer was washed with water, dried over MgSO₄, and concentrated. The residue was chromatographed on silica gel using 10% ethyl acetate/90% heptane as an eluent to give the product (53.36 g, 81%) as a light yellow oil.

6-Bromo-3-nonylbenzo[b]thiophene-2-carboxylic acid (5): To ethyl 6-bromo-3-nonylbenzo[b]thiophene-2-carboxylate (4) (51.43 g, 125.0 mmole) was added 1 M KOH aqueous solution (163 ml, 163.0 mmole) and THF (490 ml), and the reaction mixture was refluxed for 24 h. THF solvent was removed by a rotary evaporator and the residue was diluted in water (200 ml) and 3 M HCl was added to make the mixture at pH 1. The mixture was filtered, washed with water twice (200 ml) and pentane (200 ml) and dried under vacuum. A light ivory solid product (47.06 g, 98%) was obtained with mp 126-127° C.

6-Bromo-3-nonylbenzo[b]thiophene (6): To 6-bromo-3-nonylbenzo[b]thiophene-2-carboxylic acid (5) (46.00 g, 120 mmole) in quinoline (40 mL) was added copper powder (0.15 g, 2.4 mmole) and the mixture was heated at 220-240° C. until the gas evolution was stopped. The reaction mixture was quenched with 3 M HCl (300 ml) and extracted twice with ether (200 ml), and the organic layer was washed with 3 M HCl (100 ml), dried over MgSO₄, and concentrated. A fractional distillation gave a product (27.44 g, 67%) as a light yellow oil at 174-176° C./0.57 mmHg.

2,6-Dibromo-3-nonylbenzo[b]thiophene (7): A mixture of N BS (16.66 g, 93.6 mmole), 6-Bromo-3-nonylbenzo[b]thiophene (6) (26.47 g, 78.0 mmole), CH₂Cl₂(75 ml), and acetic acid (1 ml) was stirred for overnight at room temperature. The reaction mixture was filtered through a filter paper and the filter paper was washed with CH₂Cl₂(75 ml), and the organic layer was washed with 1 M KOH solution, saturated NaHCO3 solution, and brine, dried over MgSO₄. A rotary evaporation of solvent gave a product (28.34 g, 87%) as a light red oil.

6-Bromo-3-nonyl-2-benzo[b]thienylzinc bromide (8): To a slurry of active zinc (6.00 g, 91.8 mmole) in THF (60 ml) was added 2,6-dibromo-3-nonylbenzo[b]thiophene (7) (25.09 g, 60.0 mmole) in THF (10 ml) at room temperature under Ar, and the mixture was refluxed for 3 h. THF (50 ml) was added into the reaction mixture and the mixture was stood for overnight to settle down the excess zinc. The top organozinc solution was transferred into a clean flask.

Poly (3-nonylbenzo[b]thiophene-2,6-diyl) (9): To 6-bromo-3-nonyl-2-benzo[b]thienylzinc bromide (8) (0.5 M solution in THF, 120 ml, 60.0 mmole) was added Ni(dppe)Cl2 (94.2 mg, 0.18 mmole) at room temperature under Ar atmosphere, and the reaction mixture was refluxed for 24 h. The reaction was quenched by pouring the reaction mixture into a beaker containing MeOH (120 ml) and the mixture was stirred for 30 minutes at room temperature. The mixture was filtered, washed with MeOH (60 ml) and dried under vacuum. A yellow solid (13.75 g. 89%) was obtained after Soxhlet extraction with 1:1 mixture of MeOH/Hexanes for 24 h and drying under vacuum.

Two acid chlorides were prepared as described below and other acid chlorides were purchased and used without a purification.

4-Cyclohexylbutyryl chloride: To 4-cyclohexylbutyric acid (100.38 g, 589.6 mmole) was added thionyl chloride (65 ml, 106.28 g, 893.3 mmole) and DMF (1 mL), and the mixture was stirred for 30 minutes at room temperature and refluxed for 2 h. Low boiling impurities were evaporated in rotary evaporator and a fractional distillation gave the product (110.61 g, 99%) as a light yellow oil at 75° C./1.04 mmHg.

5-Phenylpentanoyl chloride: To 5-phenylpentanoic acid (101.46 g, 569.3 mmole) was added thionyl chloride (62 ml, 101.37 g, 852.1 mmole) and DMF (1 ml), and the mixture was stirred for 30 minutes at room temperature and refluxed for 2 h. Low boiling impurities were evaporated in rotary evaporator and a fractional distillation gave the product (96.08 g, 86%) as a light brown oil at 92° C./0.89 mmHg.

### Example 2

According to the procedure described in example 1 the following polythiophenes were prepared:
a) Poly (3-hexylbenzo[b]thiophene-2,6-diyl)
b) Poly (3-undecylbenzo[b]thiophene-2,6-diyl)
c) Poly (3-(2-cyclopentylethyl)benzo[b]thiophene-2,6-diyl)
d) Poly (3-(3-cyclopentylpropyl)benzo[b]thiophene-2,6-diyl)
e) Poly (3-(4-phenylbutyl)benzo[b]thiophene-2,6-diyl)

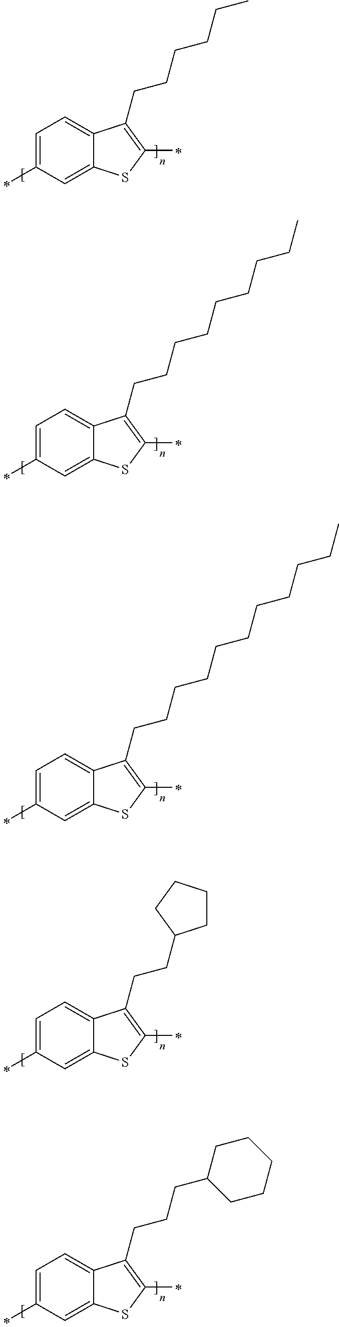

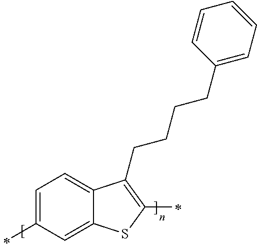

1. A polymer, comprising a group of formula (I) 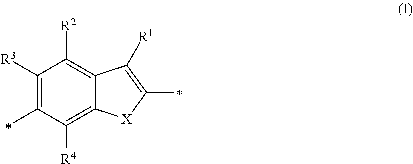
wherein
R² and R³ optionally together form a cyclic moiety,
R¹ to R⁴ are each independently selected from the group consisting of a) H, b) halogen, c) —CN, d) —NO₂, e) oxo, f) —OH, g)═C(R⁵)₂, h) a C₁₋₂₀ alkyl group, i) a C₂₋₂₀ alkenyl group, j) a C₂₋₂₀ alkynyl group, k) a C₁₋₂₀ alkoxy group, l) a C₁₋₂₀ alkylthio group, m) a C₁₋₂₀ haloalkyl group, n) a —Y—C₃₋₁₀ cycloalkyl group, o) a —Y—C₆₋₁₄ aryl group, p) a —Y-3-12 membered cycloheteroalkyl group, and q) a —Y-5-14 membered heteroaryl group,
wherein each of the C₁₋₂₀ alkyl group, the C₂₋₂₀ alkenyl group, the C₂₋₂₀ alkynyl group, the C₃₋₁₀ cycloalkyl group, the C₆₋₁₄ aryl group, the 3-12 membered cycloheteroalkyl group, and the 5-14 membered heteroaryl group is optionally substituted with 1-4 R⁵ groups, and
R⁵ is independently a) halogen, b) —CN, c) —NO₂, d) oxo, e) —OH, f) —NH₂, g) —NH(C₁₋₂₀ alkyl), h) —N(C₁₋₂₀ alkyl)₂, i) —N(C₁₋₂₀ alkyl)-C₆₋₁₄ aryl, j) —N(C₆₋₁₄ aryl)₂, k) —S(O)ₘH, 1) —S(O)ₘ—C₁₋₂₀ alkyl, m) —S(O)₂OH, n) —S(O)ₘ—OC₁₋₂₀ alkyl, o) —S(O)ₘ—OC₆₋₁₄ aryl, p) —CHO, q) —C(O)—C₁₋₂₀ alkyl, r) —C(O)—C₆₋₁₄ aryl, s) —C(O)OH, t) —C(O)—OC₁₋₂₀ alkyl, u) —C(O)—OC₆₋₁₄ aryl, v) —C(O)NH₂, w) —C(O)NH—C₁₋₂₀ alkyl, x) —C(O)N(C₁₋₂₀ alkyl)₂, y) —C(O)NH—C₆₋₁₄ aryl, z) —C(O)N(C₁₋₂₀ alkyl)-C₆₋₁₄ aryl, aa) —C(O)N(C₆₋₁₄ aryl)₂, ab) —C(S)NH₂, ac) —C(S)NH—C₁₋₂₀ alkyl, ad) —C(S)N(C₁₋₂₀ alkyl)₂, ae) —C(S)N(C₆₋₁₄ aryl)₂, af) —C(S)N(C₁₋₂₀ alkyl)-C₆₋₁₄ aryl, ag) —C(S)NH—C₆₋₁₄ aryl, ah) —S(O)ₘNH₂, ai) —S(O)ₘNH(C₁₋₂₀ alkyl), aj) —S(O)ₘN(C₁₋₂₀ alkyl)₂, ak) —S(O)ₘNH(C₆₋₁₄ aryl), al) —S(O)ₘN(C₁₋₂₀ alkyl)-C₆₋₁₄ aryl, am) —S(O)ₘN(C₆₋₁₄ aryl)₂, an) —SiH₃, ao) —SiH(C₁₋₂₀ alkyl)₂, ap) —SiH₂(C₁₋₂₀ alkyl), aq) —Si(C₁₋₂₀ alkyl)₃, ar) a C₁₋₂₀ alkyl group, as) a C₂₋₂₀ alkenyl group, at) a C₂₋₂₀ alkynyl group, au) a C₁₋₂₀ alkoxy group, av) a C₁₋₂₀ alkylthio group, aw) a C₁₋₂₀ haloalkyl group, ax) a C₃₋₁₀ cycloalkyl group, ay) a C₆₋₁₄ aryl group, az) a haloaryl group, ba) a 3-12 membered cycloheteroalkyl group, or bb) a 5-14 membered heteroaryl group,
Y is independently a divalent C₁₋₆ alkyl group, a divalent C₁₋₆ haloalkyl group, or a covalent bond,
m is independently selected from 0, 1, or 2,
X is O, S, Se, NR¹⁰, PR¹⁰, PR¹⁰R¹¹R¹², SiR¹⁰R¹¹, or CR¹⁰R¹¹,
R¹⁰, R¹¹, R¹² are each independently H, a C₁₋₃₀ alkyl group, a C₂₋₃₀ alkenyl group, a C₁₋₃₀ haloalkyl group, -L-Ar¹, -L-Ar¹—Ar¹, -L-Ar¹—R¹³, or -L-Ar¹—Ar¹—R¹³,
R¹³ is independently a C₁₋₂₀ alkyl group, a C₂₋₂₀ alkenyl group, a C₁₋₂₀ haloalkyl group, a C₁₋₂₀ alkoxy group, -L′-Ar², -L′-Ar²—Ar², -L′-Ar²—R¹⁵, or -L′-Ar²—Ar²—R¹⁵;
L is independently —O—, Y—O—Y—, —S—, —S(O)—, —Y—S—Y—, —C(O)—, —NR¹⁴C(O)—, —NR¹⁴—, —SiR¹⁴₂—, —Y—[SiR¹⁴₂]—Y—, a divalent C₁₋₃₀ alkyl group, a divalent C₁₋₃₀ alkenyl group, a divalent C₁₋₃₀ haloalkyl group, or a covalent bond,
L′ is independently —O—, —Y—O—Y—, —S—, —S(O)—, —Y—S—Y—, —C(O)—, —NR¹⁴C(O)—, —NR¹⁴—, —SiR¹⁴₂—, —Y—[SiR¹⁴₂]—Y—, a divalent C₁₋₂₀ alkyl group, a divalent C₁₋₂₀ alkenyl group, a divalent C₁₋₂₀ haloalkyl group, or a covalent bond,
Ar¹ is independently a C₆₋₁₄ aryl group or a 5-14 membered heteroaryl group, each optionally substituted with 1-5 substituents independently selected from the group consisting of halogen, —CN, a C₁₋₆ alkyl group, a C₁₋₆ alkoxy group, and a C₁₋₆ haloalkyl group
Ar² is independently a C₆₋₁₄ aryl group or a 5-14 membered heteroaryl group, each optionally substituted with 1-5 substituents independently selected from the group consisting of halogen, —CN, a C₁₋₆ alkyl group, a C₁₋₆ alkoxy group, and a C₁₋₆ haloalkyl group,
R¹⁴ is independently H, a C₁₋₆ alkyl group, or a —Y—C₆₋₁₄ aryl group, and
R¹⁵ is independently a C₁₋₂₀ alkyl group, a C₂₋₂₀ alkenyl group, a C₁₋₂₀ haloalkyl group, or a C₁₋₂₀ alkoxy group.

2. The polymer according to claim 1, comprising at least one unit of formula (IIa)
-[(A)ₐ-(B)_{b}-(C)_{c}-(D)_{d}]ₙ- (IIa)
wherein
n is greater than or equal to 2,
A and C are independently, and in the case of multiple presence each independently, a group of the formula (I),
B and D are independently, and in the case of multiple presence each independently, a group selected from CR¹⁰═CR¹¹, —C≡C—, arylene and heteroarylene, which is optionally substituted by one or more R¹ groups,
a, b, c, d are each independently 0 or an integer value from 1 to 10, with the condition that a+b+c+d are >0 and, in at least one of repeating [(A)ₐ-(B)_{b}-(C)_{c}-(D)_{d}] groups, at least one a and one c is greater than or equal to 1 and at least one a and d is greater than or equal to 1, and
n, X, R¹, R², R¹⁰ and R¹¹ are each as defined in formula (I), and where the repeating [(A)ₐ-(B)_{b}-(C)_{c}-(D)_{d}] groups are the same or different.

3. The polymer according to claim 2, comprising at least one unit of formula (IIb)
-[(A)ₐ-(B)_{b}]ₙ- (IIb),
wherein
A is in each case, independently, a group of the formula (I),
B is in each case, independently, an arylene heteroarylene group, which is optionally substituted by one or more R¹ groups,
a and b are each independently an integer value from 0 to 10, with the condition that a+b are >0, and
n is greater than 1.

4. The polymer according to claim 2, wherein B and/or D are each independently
1,4-phenylene, fluorinated 1,4-phenylene, 2,5-pyridine, 2,5-pyrimidine, p,p′-biphenyl, naphthalene-2,6-diyl, thiophene-2,5-diyl, fluorinated or alkylated thiophene-2,5-diyl, fluorinated benzo[1,2-b:4,5-b′]dithiophene, 2,5-thiazole, 2,5-thiadiazole, 2,5-oxazole, or 2,5-oxadiazole,
each of which being optionally unsubstituted or mono- or polysubstituted by L,
wherein L is F, Cl, Br, or an alkyl, alkoxy, alkylcarbonyl or alkoxycarbonyl group having from 1 to 20 carbon atoms, where one or more hydrogen atoms are optionally replaced by F or Cl, C₁-C₂₀-alkenyl, C₁-C₂₀-alkynyl, C₁-C₂₀-thioalkyl, C₁-C₂₀-silyl, C₁-C₂₀-ester, C₁-C₂₀-amino, or C₁-C₂₀-fluoroalkyl.

5. The polymer according to claim 2, wherein B and/or D are each independently selected from the group consisting of 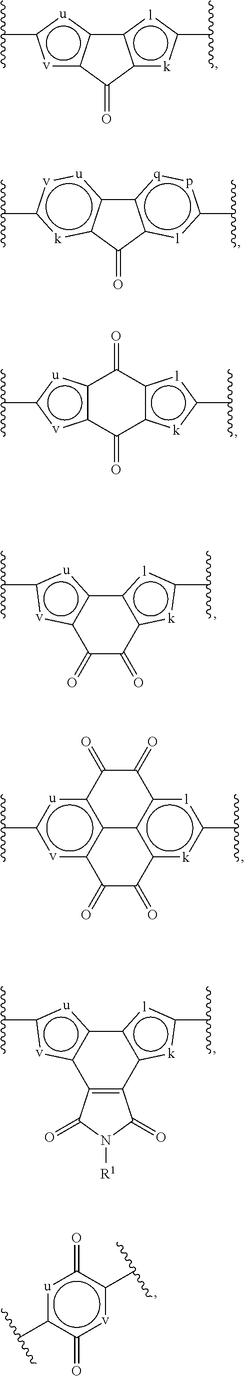 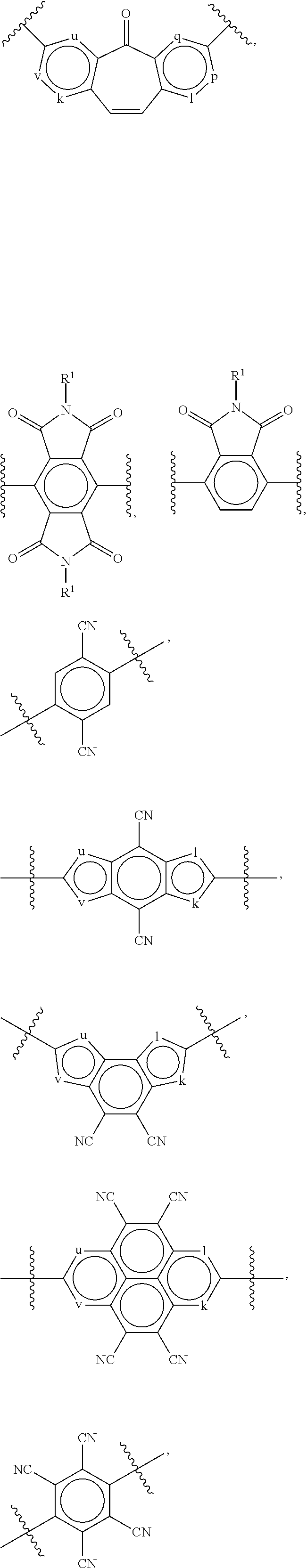 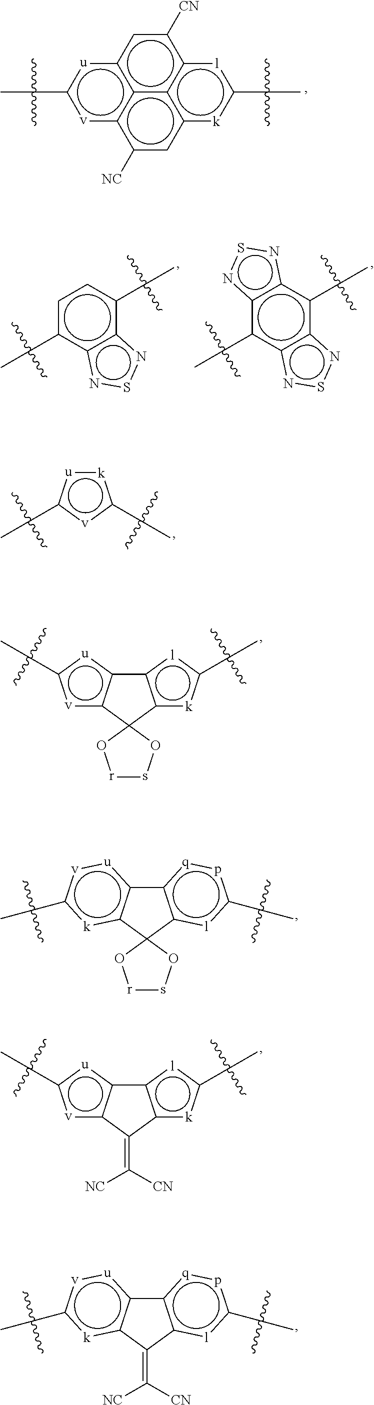 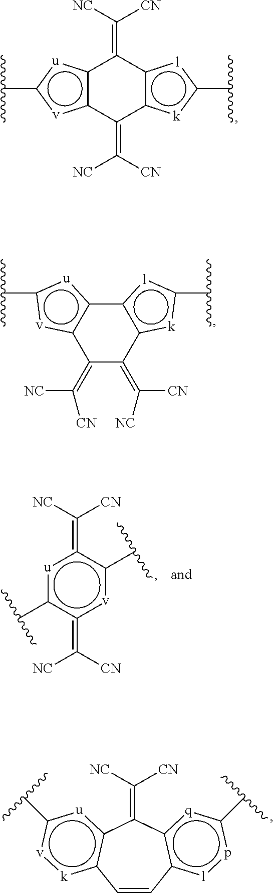
wherein
k, l, p, q, u, and v independently are —S—, —C═C—, ═CH—, ═CR¹—, ═SiH—, ═SiR¹—, ═N—, or ═P—; and
r and s independently are CH₂, CHR¹, or C(R¹)₂.

6. The polymer according to claim 2, comprising at least one unit selected from the formulae 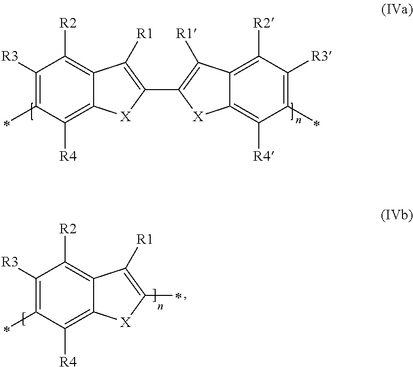
wherein R1′ to R4′ are each independently, and independently of R1 to R4, as defined for R1 to R4.

7. A semiconductor, charge transport material, thin-film transistor, semiconductor component, sensor, electrode material, optical waveguide, or electrographic device, comprising the polymer according to claim 1.

8. A composition, comprising at least one of the polymer of claim 1 dissolved or dispersed in a liquid medium.

9. A thin film semiconductor comprising at least one of the polymer of claim 1.

10. A composite, comprising:
a substrate; and
the thin film semiconductor of claim 9 deposited on the substrate.

11. A process for preparation of a composite, the process comprising:
dissolving the polymer according to claim 1 in a liquid medium to form a solution;
depositing the solution on a substrate; and
removing the solvent to form a thin film semiconductor on the substrate,
wherein the composite comprises the substrate and the thin film semiconductor deposited on the substrate.

12. The process according to claim 11, wherein the solution is deposited by spin coating or printing.

13. A field effect transistor device, comprising the thin film semiconductor of claim 9.

14. A photovoltaic device, comprising the thin film semiconductor of claim 9.

15. An organic light emitting diode device comprising the thin film semiconductor of claim 9.

16. A polymer according to claim 3, wherein B and/or D are each independently
1,4-phenylene, fluorinated 1,4-phenylene, 2,5-pyridine, 2,5-pyrimidine, p,p′-biphenyl, naphthalene-2,6-diyl, thiophene-2,5-diyl, fluorinated or alkylated thiophene-2,5-diyl, fluorinated benzo[1,2-b:4,5-b′]dithiophene, 2,5-thiazole, 2,5-thiadiazole, 2,5-oxazole, or 2,5-oxadiazole,
each of which being optionally unsubstituted or mono- or polysubstituted by L,
wherein L is F, Cl, Br, or an alkyl, alkoxy, alkylcarbonyl or alkoxycarbonyl group having from 1 to 20 carbon atoms, where one or more hydrogen atoms are optionally replaced by F or Cl, C₁-C₂₀-alkenyl, C₁-C₂₀-alkynyl, C₁-C₂₀-thioalkyl, C₁-C₂₀-silyl, C₁-C₂₀-ester, C₁-C₂₀-amino, or C₁-C₂₀-fluoroalkyl.

17. A polymer according to claim 3, wherein B is in each independently selected from the group consisting of 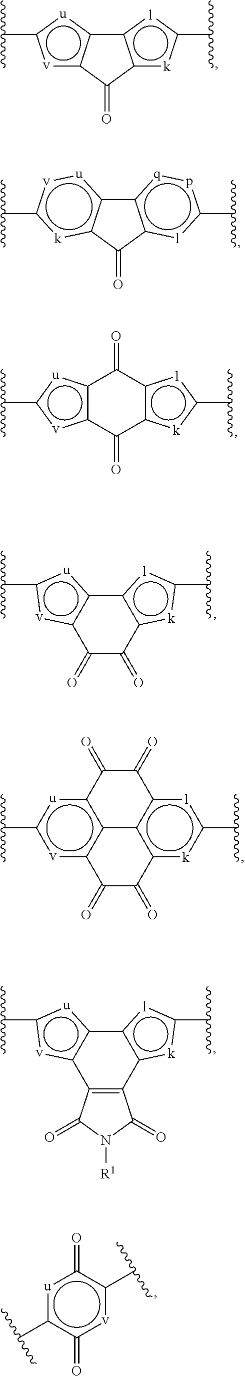 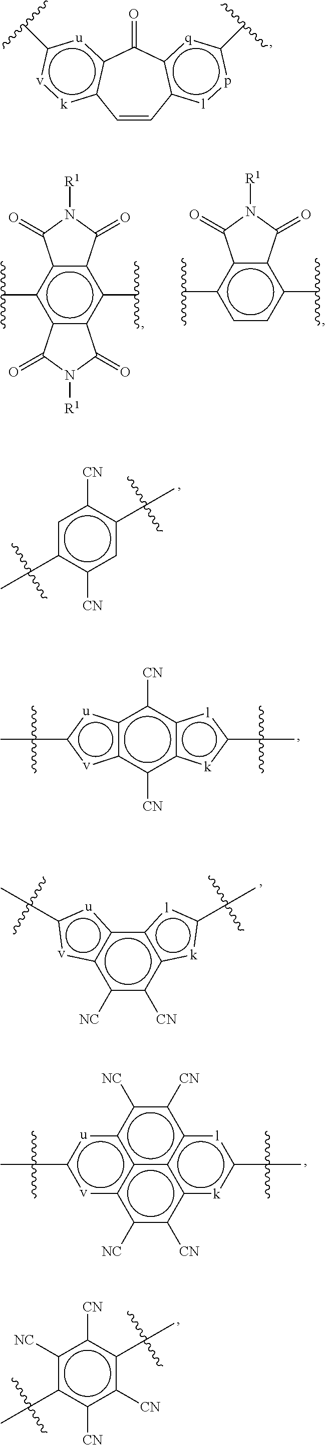 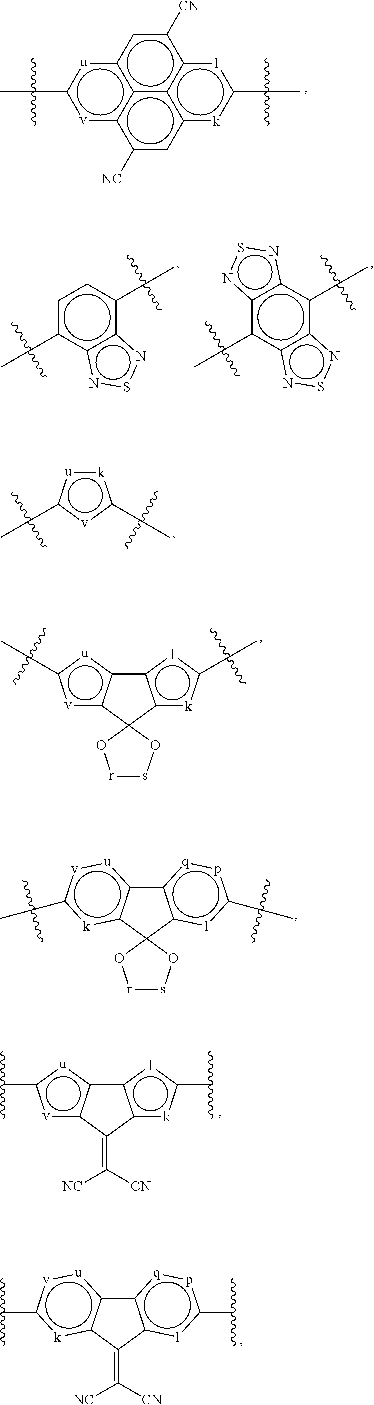 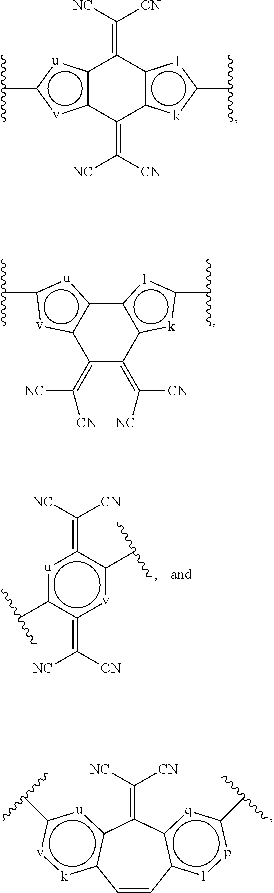
wherein
k, l, p, q, u, and v independently are —S—, —C═C—, ═CH—, ═CR¹—, ═SiH—, ═SiR¹—, ═N—, or ═P—; and
r and s independently are CH₂, CHR¹, or C(R¹)₂.

18. A field effect transistor device, photovoltaic device, or organic light emitting diode device, comprising the composite of claim 10.

19. The polymer according to claim 1, comprising at least one unit of formula (IIb)
-[(A)ₐ-(B)_{b}]ₙ- (IIb),
wherein
A is in each case, independently, a group of the formula (I),
B is in each case, independently, an arylene heteroarylene group, which is optionally substituted by one or more R¹ groups,
a and b are each independently an integer value from 0 to 10, with the condition that a+b are >0, and
n is greater than 1.

20. The polymer according to claim 2, wherein A and C are independently, and in the case of multiple presence each independently, a group of the formula (IVa) or (IVb), 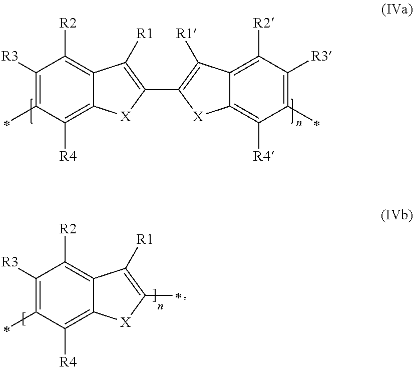
wherein R1′ to R4′ are each independently, and independently of R1 to R4, as defined for R1 to R4.
